(19) United States
(12) Patent Application Publication
(10) Pub. No.: US 2026/0112412 A1
(43) Pub. Date: Apr. 23, 2026

(54) MEMORY DEVICE WITH A THREE-DIMENSIONAL VERTICAL STRUCTURE, AND METHOD FOR DRIVING WORD LINES OF THE MEMORY DEVICE

(71) Applicant: Micron Technology, Inc., Boise, ID (US)

(72) Inventors: Efrem Bolandrina, Fiorano Al Serio (IT); Andrea Martinelli, Bergamo (IT); Christophe Vincent Antoine Laurent, Agrate Brianza (IT); Ferdinando Bedeschi, Biassono (IT); Paolo Fantini, Vimercate (IT)

(21) Appl. No.: 19/423,437

(22) Filed: Dec. 17, 2025

Related U.S. Application Data
(63) Continuation of application No. PCT/IB2024/053173, filed on Apr. 2, 2024.

(51) Int. Cl. G11C 13/00; H10B 63/00

(52) U.S. Cl. CPC G11C 13/0028; H10B 63/24; G11C 2213/71

(57) ABSTRACT

It is disclosed a memory device comprising a plurality of memory cells arranged in a three-dimensional array having a plurality of levels above a substrate, comprising a plurality of conductive word lines extending over a respective level and coupled to said plurality of memory cells, each word line being connected to a respective step of a staircase positioned in a staircase area (306, 710) outside an active area (702) of the array of the plurality of memory cells. The memory device further comprises a plurality of word line drivers (500) for the corresponding plurality of word lines and comprises a plurality of Through Array Via elements (305; 305a, 305b, 305c, 305d) for the corresponding plurality of word lines. The plurality of word line drivers and the plurality of Through Array Via elements are positioned in the staircase area (306).

### PRIORITY APPLICATION

This application is a continuation under 35 U.S.C. § 111 (a) and claims the benefit of priority of International Patent Application Serial No. PCT/IB2024/053173, filed on 2 Apr. 2024, and published in English on 9 Oct. 2025 as WO/2025/210376, which is incorporated by reference herein in its entirety.

### DESCRIPTION

### Technical Field

The present disclosure relates to a memory device and to a method for accessing a memory device.

More in particular, the present disclosure relates to a Thin Film Transistor-based word line driving and decoding memory device and related methods.

### Background

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often denoted by a logic 1 or a logic 0. To access the stored information, a component may read (e.g., sense, detect, retrieve, identify, determine, evaluate) a stored state in the memory device. To store information, a component may write (e.g., program, set, assign) the state in the memory device.

Various types of memory devices and memory cells exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

Memory devices with cross-point architecture are known for example from WO 2021/186199 A1 and WO 2021/240203, wherein the memory cells are arranged in a three-dimensional (3D) vertical array including word lines and digit lines.

Each memory cell includes a dielectric material and a storage element material. The storage element material is for example chalcogenide material, which is a self selecting storage element material (e.g., a material that may serve as both a select device and a storage element).

A memory cell is formed at a topological cross-point between a word line and a digit line orthogonal to each other, wherein a memory cell is accessed through a word line and a digit line which is in a form of conductive pillar extending vertically.

A pillar selection layer is formed under the memory array and it has thin film transistors (TFTs) formed therein for accessing the memory cells, wherein a TFT is associated to each pillar for selecting a digit line.

The cross-point architecture may offer relatively high-density data storage with lower production costs compared to other memory architectures. For example, the cross-point architecture may have memory cells with a reduced area and, resultantly, an increased memory cell density compared to other architectures.

Decoding circuitry for word lines and digit lines are formed in the substrate under the 3D array of memory cells, in particular using CMOS circuitry under the array, thus reducing the space available for placing other circuitry for operating the memory device, such as sense amplifiers and biasing circuits that are also placed under the array.

Solutions for saving space in the memory array region may be desired.

Memory cells are addressed for access, e.g., during a read or a write operation, via access line drivers, for example via bit line drivers and via word line drivers. Word line drivers need to drive a high current, since a large number of memory cells may be simultaneously activated (in read and write operation) on a same word line.

As a consequence, the word line driver must have a large driving capability, i.e., large size and large CMOS area required. This leads to high cost and complexity of the final device because the CMOS circuitry is expensive and difficult to realize.

### SUMMARY

An object of the present disclosure is to reduce the CMOS area dedicated to the realization of word line drivers, thus increasing the area available under the 3D array of memory cells for placing circuitry for operating the memory device, so as to reduce the overall cost of the memory device.

These and other objects are fully achieved by virtue of a memory device having the characteristics defined in independent claim 1, by a method for driving a word line in a memory device having the characteristics defined in claim 11 and by a word line decoder for the memory device having the characteristics defined in claim 16.

Additional features of embodiments are specified in the dependent claims, whose subject-matter is to be understood as forming integral or integrating part of the present description.

### BRIEF DESCRIPTION OF THE DRAWINGS

Further characteristic and advantages of the present disclosure will become apparent from the following description, provided merely by way of non-limiting example, with reference to the attached drawings, in which:

FIG. 1 illustrates an example of a memory device that supports TFT-based word line decoding in a memory array according to examples disclosed herein;

FIG. 2 illustrates a top view of an example of a memory array that supports TFT-based word line decoding in a memory array according to examples disclosed herein;

FIGS. 3A and 3B illustrate side views of an example of a memory array that supports TFT-based word line decoding a memory array according to examples disclosed herein;

FIG. 4 shows word lines belonging to different levels of a three-dimensional arrangement of memory cells according to examples disclosed herein;

FIG. 5 shows a circuit of a word line driver that supports TFT-based word line decoding according to examples disclosed herein;

FIGS. 6 and 7 show the circuit of FIG. 5 in different operative conditions that support TFT-based word line decoding;

FIG. 8 shows word lines connected to a staircase in a memory device that supports TFT-based word line decoding according to examples disclosed herein;

FIGS. 9a, 9b show two examples of arrangements of word line driving transistors according to examples disclosed herein;

FIG. 10 shows a first example of a memory device that supports TFT-based word line decoding in accordance with examples as disclosed herein;

FIG. 11 shows a second example of a memory device that supports TFT-based word line decoding in accordance with examples as disclosed herein;

FIG. 12 shows a top view of a tile in an array of a memory device that supports TFT-based word line decoding with an enlarged view of the staircase area; and

FIG. 13 shows a flowchart illustrating a method that supports TFT-based word line decoding in accordance with examples as disclosed herein.

### DETAILED DESCRIPTION

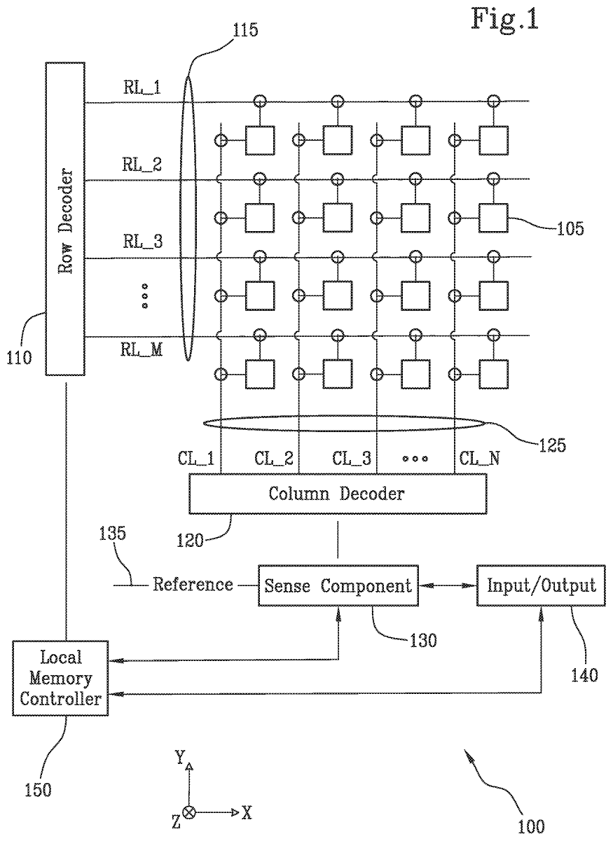

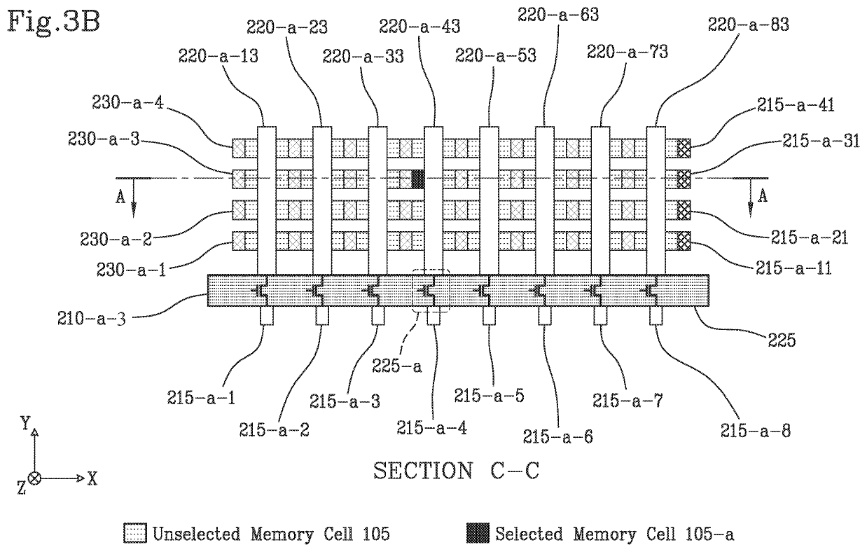

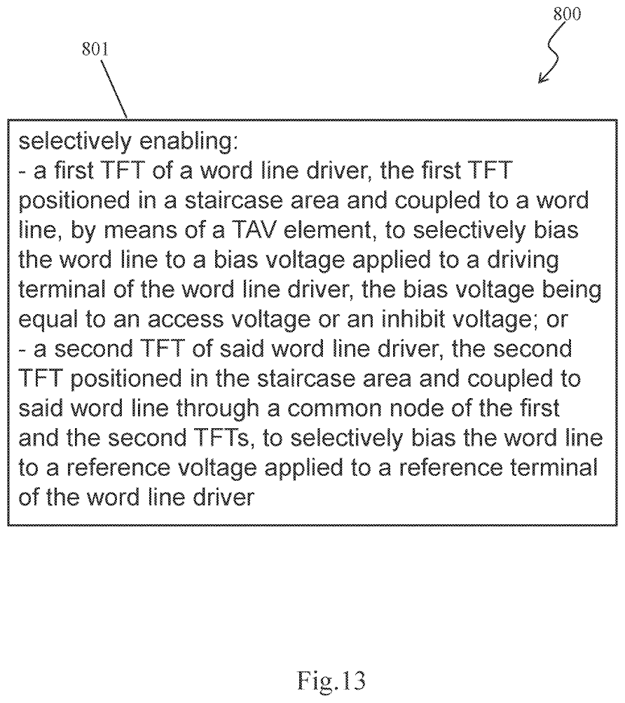

Features of the disclosure are initially described in the context of memory devices and arrays with reference to FIGS. 1, 2, 3A, and 3B. Features of the disclosure are described in the context of a portion of memory devices and word line driver with reference to FIGS. 4-5, 6, 7, 8, 9a-9b, 10, 11 and 12 and a driving method described with reference to FIG. 13.

FIG. 1 illustrates a memory device 100 that supports a Thin Film Transistor-based (TFT-based) word line decoding in a memory array. The memory device 100 may include one or more memory cells 105 that each may be programmable to store different logic states, for example, one bit of information at a time (e.g., a logic 0 or a logic 1).

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and column lines 125. In some examples, memory cells 105 may also be arranged (e.g., addressed) along an illustrative z-direction, such as in an implementation of sets of memory cells 105 being located at different levels (e.g., layers, decks, tiers, planes) along the illustrative z-direction. In some examples, a memory device 100 that includes memory cells 105 at different levels may be supported by a different configuration of access lines, decoders, and other supporting circuitry than shown.

The devices discussed herein, including the array of memory cells 105, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The term “layer” or “level” or “tier” used herein refers to a stratum or sheet of a geometrical structure (e.g., relative to a substrate). Each layer or level or tier may have three dimensions (e.g., height, width, and depth) and may cover at least a portion of a surface. For example, a layer or level or tier may be a three-dimensional structure where two dimensions are greater than a third, e.g., a thin film. Layers or levels or tiers may include different elements, components, or materials. In some examples, one layer or level or tier may be composed of two or more sublayers or sublevels.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 and/or the column line 125), a memory cell 105 may be accessed in accordance with their intersection. Accessing the memory cells 105 may be controlled through one or more decoders, such as a row decoder 110 or a column decoder 120. For example, a row decoder 110 may receive a row address from a local memory controller 150 and activate a row line 115 based on the received row address. A column decoder 120 may receive a column address from the local memory controller 150 and may activate a column line 125 based on the received column address.

A sense component 130 may be operable to detect a state of a memory cell 105 and determine a logic state of the memory cell 105 based on the detected state. The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 by receiving information (e.g., commands, data) from one or more different controllers (remote or associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 may be operable to perform one or more access operations on one or more memory cells 105 of the memory device 100. Examples of access operations may include a write operation, a read operation, a refresh operation, a precharge operation or an activate operation, among others.

The memory cell 105 may be accessed (e.g., written to, read from) based on an electrical current through the memory cell 105. For example, a logic state may be written to a memory cell 105 based on a current driven through the memory cell 105 (e.g., an amount of current, a direction of current), and a logic state may be read from the memory cell 105 based on a current (e.g., a presence of current, an absence of current, an amount of current) through the memory cell 105 in response to a read bias across the memory cell 105. In some examples, memory cells 105 may be accessed based on various decoding architectures, which may implement transistors or other switching components (e.g., of a row decoder 110, of a column decoder 120) to access selected memory cells 105 in accordance with an addressing scheme. For example, for accessing certain memory cells 105, a voltage may be applied to gates of some transistors for coupling some conductive structures (e.g., for coupling access lines across a channel of the transistors), and the voltage may not be applied to gates of other transistors to maintain an isolation between other conductive structures.

For a given set of memory cells 105 (e.g., a section of memory cells, a tile of memory cells), a driver associated with driving access currents through the memory cells 105 may be associated with a relatively higher current than a driver associated with coupling conductive structures (e.g., a driver associated with biasing transistor gates, a driver associated with activating transistor channels, a driver associated with a row decoder, a driver associated with a column decoder) in accordance with an addressing scheme of the set of memory cells 105.

Drivers associated with different current levels for a set of memory cells 105 may be configured to facilitate various aspects of layout or operation of a memory device 100. For example, a set of memory cells 105 of a memory device 100 may be associated with an array of conductive structures, where such structures (e.g., along a direction of the array) may be coupled using a set of transistors or other switching components that are activated by a first driver (e.g., a selection driver, a gate driver, a driver associated with a row decoder 110, a driver associated with a column decoder 120). The set of memory cells 105 may be divided into two or more subsets of memory cells 105 (e.g., with different subsets arranged along the direction of the array), where each subset may be associated with a respective second driver (e.g., a read driver, a write driver, a memory cell current driver) for driving access currents through memory cells 105 of the subset.

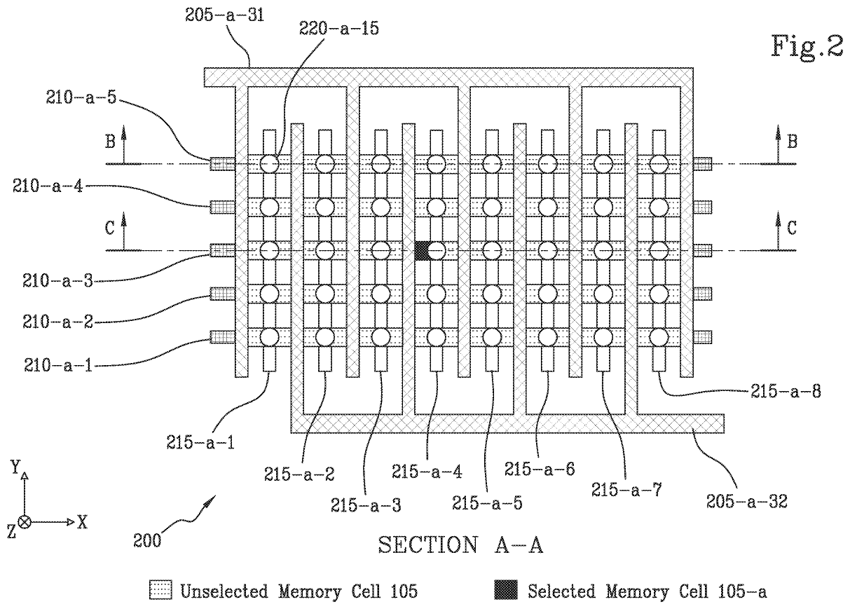

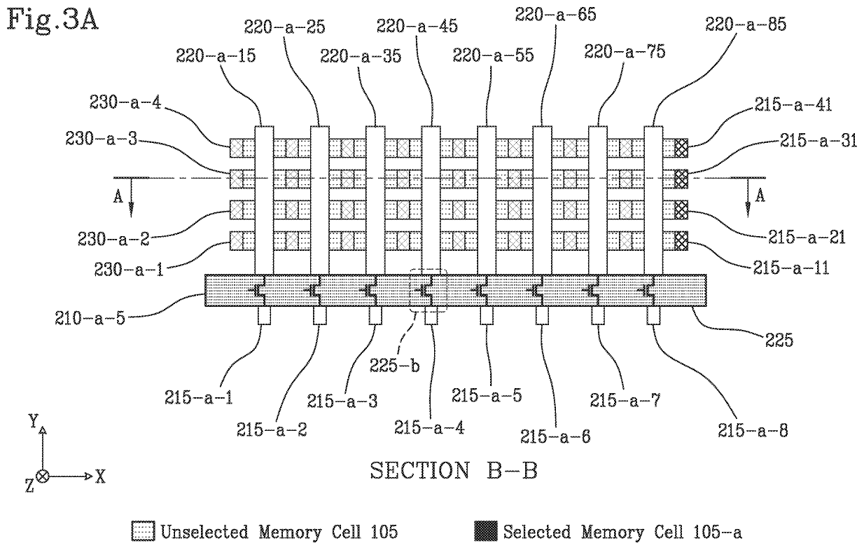

FIGS. 2, 3A and 3B illustrate an example of a memory array 200 that supports TFT-based word line decoding that may be included in a memory device 100 and illustrate an example of a three-dimensional arrangement of memory cells 105 that may be accessed by various conductive structures (e.g., access lines).

FIG. 2 illustrates a top section view (e.g., SECTION A-A) of the memory array 200 relative to a cut plane A-A as shown in FIGS. 3A and 3B.

FIG. 3A illustrates a side section view (e.g., SECTION B-B) of the memory array 200 relative to a cut plane B-B as shown in FIG. 2.

FIG. 3B illustrates a side section view (e.g., SECTION C-C) of the memory array 200 relative to a cut plane C-C as shown in FIG. 2.

The section views may be examples of cross-sectional views of the memory array 200 with some aspects (e.g., dielectric structures, adhesion or barrier materials, etc.) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features.

In the memory array 200, memory cells 105 and word lines 205 may be distributed along the z-direction according to a plurality of levels 230 (e.g., decks, layers, tiers, planes, as illustrated in FIGS. 3A and 3B). In some examples, the z-direction may be orthogonal to a substrate layer (not shown) of the memory array 200, which may be below the illustrated structures along the z-direction. Although the memory array 200 includes four levels 230 indicated with 230-a-1, 230-a-2, 230-a-3, 230-a-4, a memory array 200 in accordance with examples as disclosed herein may include any quantity of two or more levels 230 (e.g., 64 levels, 128 levels, 144 levels, etc.) along the z-direction.

The word lines 205 may be formed in a comb structure, including portions (e.g., projections, tines) extending along the y-direction through gaps (e.g., alternating gaps) between pillars 220. For example, as illustrated, the memory array 200 may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 of a level 230 may be associated with a first memory cell 105 on a first side (e.g., along the x-direction) of a given pillar 220 and an even word line of the same level 230 may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line that is formed by one or more conductive materials (e.g., one or more metal portions, one or more metal alloy portions). As illustrated, the pillars 220 may be arranged in a two-dimensional array (e.g., in an XY-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). A memory array 200 may include any quantity of pillars 220 along the x-direction and the y-direction. Further, as illustrated, each pillar 220 may be coupled with a respective set of memory cells 105 (e.g., along the z-direction, one or more memory cells 105 for each level 230).

Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105 of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2) which may have an opposite sign relative to the first voltage. Regarding the selected memory cell 105-a, a corresponding access bias (e.g., the first voltage) may be applied to the selected word line 205-a-32, while other unselected word lines 205 may be biased to a deselection reference voltage (for example grounded, e.g. biased to 0 Volt). In some examples, a word line bias may be provided by a word line driver (not shown) coupled with one or more of the word lines 205.

To apply a corresponding access bias (e.g, the second voltage) to a pillar 220, the pillars 220 may be configured to be selectively coupled with a sense line 215 (e.g., a digit line, a column line, an access line extending along the y-direction) via a respective transistor 225. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be coupled to a ground reference voltage (e.g., biased to 0 Volt) or otherwise biased with an activation voltage. In an example where the transistors 225 are n-type transistors, the gate line 210-a-3 being biased with a voltage that is relatively higher than the sense line 215-a-4 may activate the transistor 225-a (e.g., causing the transistor 225-a to operate in a conducting state), thereby coupling the pillar 220-a-43 with the sense line 215-a-4 and biasing the pillar 220-a-43 with the associated access bias.

In some examples, unselected pillars 220 of the memory array 200 may be electrically floating when the transistor 225-a is activated, or may be coupled with another voltage source (e.g., grounded, via a high-resistance path, via a leakage path, along an end of the pillars 220 opposite from the transistors 225) to avoid a voltage drift of the pillars 220. For example, a ground reference voltage being applied through a respective generator to the gate line 210-a-3 may not activate other transistors coupled with the gate line 210-a-3, because the ground reference voltage of the gate line 210-a-3 may not be greater than the voltage of the other sense lines 215 (e.g., which may be biased with a ground reference voltage or may be floating). Further, other unselected gate lines 210, including gate line 210-a-5 as shown in FIG. 3A, may be biased with a voltage equal to or similar to an access bias (e.g., −V_{read}/2, or some other negative bias or bias relatively near the access bias voltage), such that none of the transistors 225 along an unselected gate line 210 are activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

For a given set of memory cells 105 associated with the memory array 200 (e.g., a section of memory cells, a tile of memory cells), a driver associated with driving access currents through the memory cells 105 (e.g., a driver coupled with the word lines 205, a word line driver, a driver coupled with sense lines 215) may be associated with a relatively higher current than a driver associated with coupling conductive structures (e.g., a driver associated with activating transistors 225, a gate line driver) in accordance with an addressing scheme of the memory array 200. In some examples, a driver associated with a relatively higher current may be associated with a relatively larger footprint of the memory array 200 (e.g., along the x-direction, along the y-direction), or a relatively higher current density through interconnecting structures such as socket regions, among other differences compared with a driver associated with a relatively lower current.

In a memory device 100 as above disclosed, the comb structures of the word lines are coupled to circuitry placed underneath the three-dimensional arrangement of memory cells 105 through a staircase 300, as it will be explained more in detail afterwards.

FIG. 4 shows word lines 205-a-21, . . . , 205-a-31, . . . , 205-a-41 belonging to different levels 230 of the three-dimensional arrangement of memory cells 105 connected to a respective step 300a, 300b, 300c of a staircase 300, wherein the steps 300a, 300b, 300c are end portions of word lines 205-a-21, 205-a-31, 205-a-41 and are configured for biasing the respective word line; in other words, word line 205-a-21 is connected to step 300a of the staircase 300, word line 205-a-31 is connected to step 300b of the staircase 300 and word line 205-a-41 is connected to step 300c of the staircase 300.

In FIG. 4, the word lines 205-a-21, 205-a-31 and 205-a-41 are not entirely shown in their longitudinal extension for clarity reason, in order to avoid superposition of many lines in the drawing.

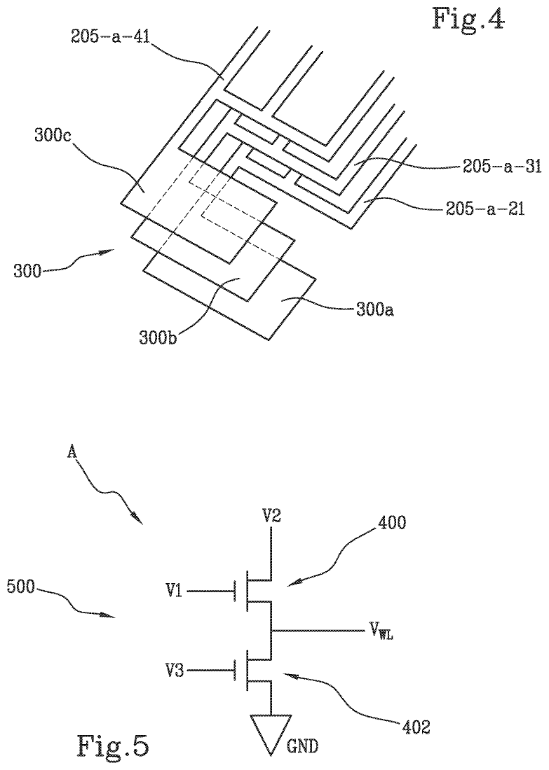

FIG. 5 shows a circuit (i.e. electrical scheme) of a word line driver 500 that supports TFT-based word line decoding. Word line driver 500 in FIG. 5 is used to realize the word line drivers (for each level 230), wherein a word line driver 500 comprises a couple of n-MOS driver transistors 400, 402 as shown in FIG. 5; in particular, driver transistors 400 and 402 may be Thin Film transistors (TFT).

Different values of a first bias voltage V1, a second bias voltage V2, a third bias voltage V3 can be applied through a respective generator at the terminals of the driver transistors 400 and 402 (with respect to a deselection reference voltage, such as a ground reference voltage GND), thus obtaining an output voltage V_{WL} adapted to be applied to a respective word line (for example, the word line 205-a-32 or the word line 205-a-31 of FIG. 2 and/or FIG. 3).

Depending on the value of the output voltage V_{WL}, a word line 205 is selected or is not selected.

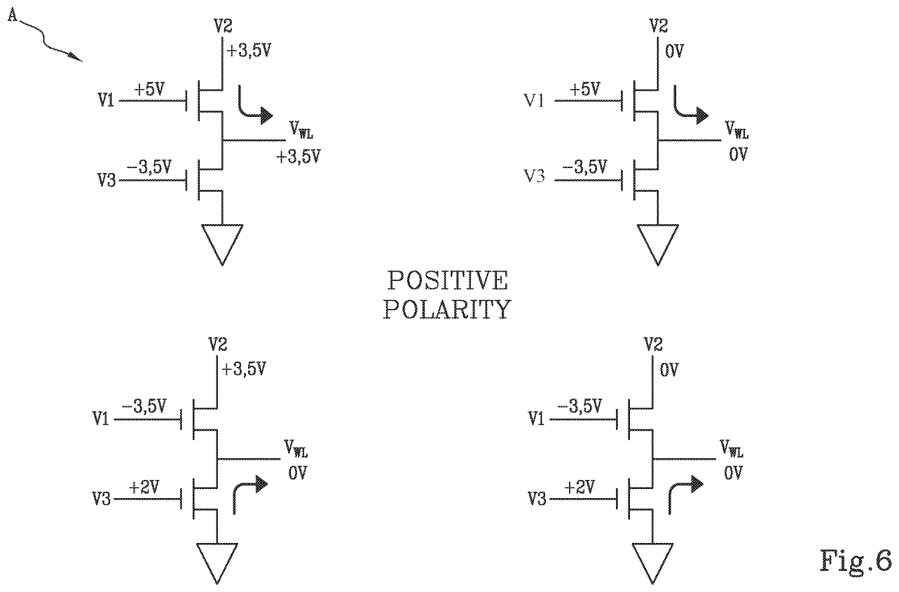

FIGS. 6 and 7 show the circuit of FIG. 5 in different operative conditions that support TFT-based word line decoding, depending on the values of the first, second, third bias voltages V1, V2, V3 applied to the terminals of the n-MOS driver transistors 400, 402.

The configuration indicated by an arrow A in FIG. 6 represents the operative condition of the word line driver 500 in which the output voltage V_{WL} on the selected word line 205 has a positive value (with respect to a negative value applied to the selected bit line-not shown), thus allowing selection of the memory cell coupled between the selected word line and the selected bit line. The other operative conditions depicted in FIG. 6 refer to unselected word lines.

In some cases, the unselected word lines share some common signal with the selected word line and/or with other unselected word lines.

For example, the two word line drivers in the top of FIG. 6 share a common value of the first bias voltage V1 equal to the activation voltage (for example, V1=+5 Volt) and a common value of the third bias voltage V3 equal to the deactivation voltage (for example, V3=−3.5 Volt), while the two word line drivers in the bottom of FIG. 6 share a common value of the first bias voltage V1 equal to the deactivation voltage (for example, V1=−3.5 Volt) and a common value of the third bias voltage V3 equal to the activation voltage (for example, V3=+2 Volt); moreover, the two word line drivers on the left of FIG. 6 share a common value of the second bias voltage V2 equal to an access voltage (for example, V2=+3.5 Volt) and the two word line drivers on the right of FIG. 6 share a common value of the second bias voltage V2 equal to an inhibit voltage (for example, V2=0 Volt).

The configuration indicated by an arrow A in FIG. 7 represents the operative condition in which the output voltage V_{WL} on the selected word line 205 has a negative value (with respect to a positive value applied to the addressed bit line—not shown), thus allowing selection of the memory cell coupled between the selected word line and the selected bit line. The other operative conditions depicted in FIG. 7 refer to unselected word lines.

In some cases, the unselected word lines share some common signal with the selected word line and/or with other unselected word lines.

For example, the two word line drivers in the top of FIG. 7 share a common value of the first bias voltage V1 equal to the activation voltage (for example, V1=0 Volt) and a common value of the third bias voltage V3 equal to the deactivation voltage (for example, V3=−3.5V), while the two word line drivers in the bottom of FIG. 7 share a common value of the first bias voltage V1 equal to the deactivation voltage (for example, V1=−3,5 Volt) and a common value of the third bias voltage V3 equal to the activation voltage (for example, V3=+2 Volt); moreover, the two word line drivers on the left of FIG. 7 share a common value of the second bias voltage V2 equal to an access voltage (for example, V2=−3.5 Volt) and the two word line drivers on the right of FIG. 7 share a common value of the second bias voltage V2 equal to an inhibit voltage (for example, V2=0 Volt).

Therefore FIGS. 6 and 7 show possible configurations of the word line driver 500 that allow driving the respective selected word line 205 to a positive (FIG. 6) or negative (FIG. 7) voltage, while biasing unselected word lines (e.g., word lines that share some common lines with the selected word line) to a deselection reference voltage (for example equal to ground) or floating, in order to avoid selection of cells coupled thereto.

The word line drivers of FIGS. 5, 6 and 7 may comprise a pair of Thin Film transistors, TFT. The TFT transistors may be n-type transistors, in some embodiments.

The word line drivers may be formed in a staircase area 306, as further described below. The staircase area is adjacent to (e.g., neighbouring or proximate to but not overlapping) the active area, the active area comprising active cells.

In an example of a memory device, a transistor 225 (e.g., an off-Si N-TFT) is available for the selection of each pillar 220; other transistors 225 (referred to as “word line driving transistors” 225) may be used for the realization of TFT-based word line decoders.

The word line driving transistors 225 for word line decoding may be located under the staircase 300 in the staircase area 306, so that no additional elements are used for word line decoding.

The word line driving transistors 225 may be realized in the same technology as the transistors used for pillar selection in the array area, e.g. the word line driving transistors may also be off-Si N-channel Thin Film Transistors, TFT; moreover, the word line driving transistors 225 may be fabricated during the same processing steps as transistors 225 for pillar selection 225.

In particular, a whole word line decoding architecture, e.g. the circuit of the word line driver 500 of FIG. 5, may be obtained without any use of the substrate of the silicon area under the 3D array of memory cells, such substrate area being usually referred to as CMOS Under Array area (CUA). In this way CMOS circuitry under the 3D array of memory cells may have other functions, such as pre-driver circuitry for word lines, gate lines and/or bit lines, voltage sources, sense amplifiers, among others.

In accordance with examples as disclosed herein, each word line driver 500 may be built with a matrix of Thin Film transistors 225, wherein the number of Thin Film Transistors 225 employed for each word line driver 500 depends upon the area and the shape of the steps 300a, 300b, 300c of the staircase 300: the larger is the step 300a, 300b, 300c, the higher is the number of Thin Film Transistors 225 available for each word line driver 500.

Each step 300a, 300b, 300c, 300d of the staircase 300 is coupled to the even word lines (or, respectively, odd word lines-only one subset of the even or odd word lines is depicted) at a given level 230. In order to select a memory cell 105, a pillar 220 and an odd (or an even) word line 205 have to be selected, this selection being performed by means of the word line driver 500.

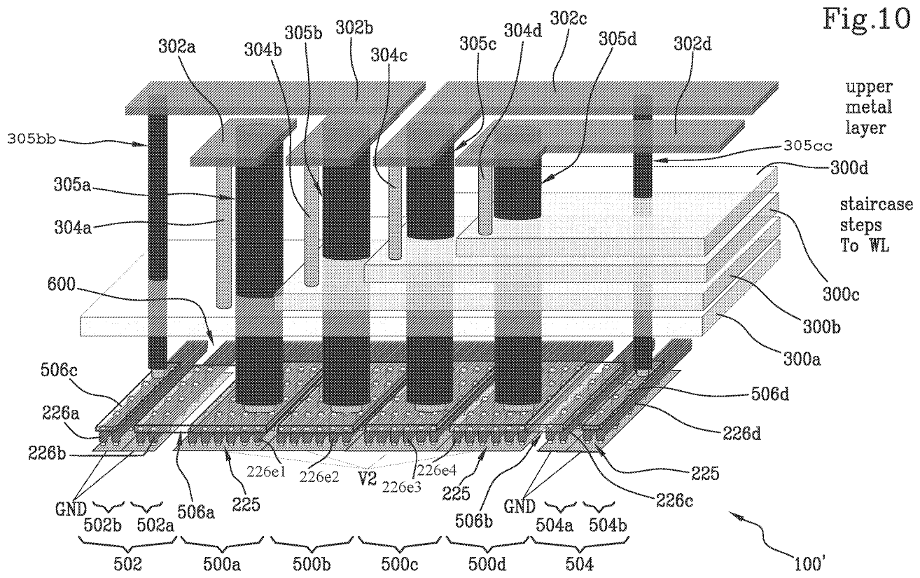

In an example of a memory device, under each step 300a, 300b, 300c of the staircase 300 two word line driving transistors (see FIG. 10) are fit corresponding to the n-MOS driver transistors 400, 402 of FIG. 5, in order to implement the decoding technique above disclosed with reference to FIGS. 5, 6 and 7.

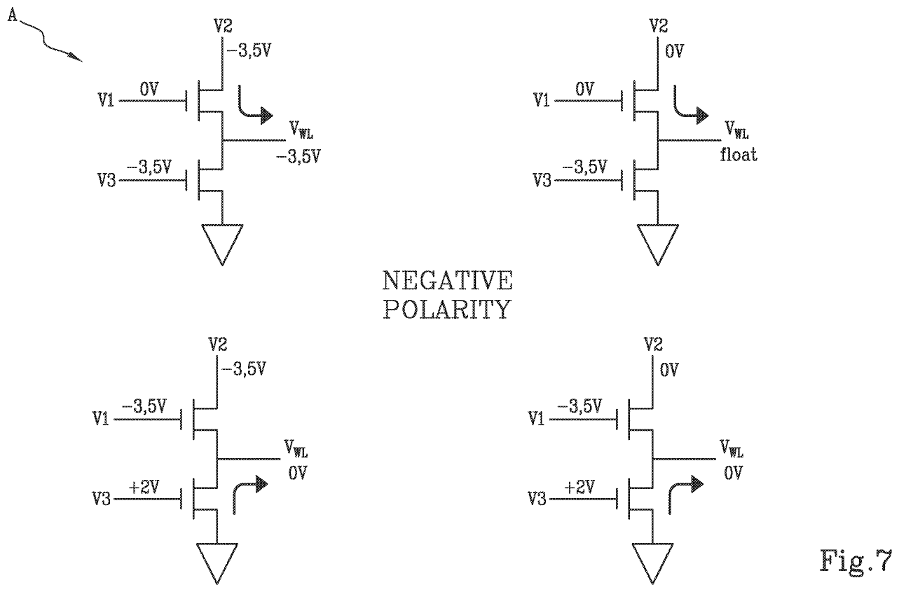

FIG. 8 shows word lines 205 connected to the staircase 300 in a memory device 100 that supports TFT-based word line decoding. FIG. 8 shows more details with respect to FIG. 4.

As shown in FIG. 8, each word line 205 (only fingers of top-most word line layer are shown for clarity) is coupled from respective step 300a, 300b, 300c of the staircase 300 to a respective word line driver 500 (not shown) via a respective conductive plug 304, a respective upper metal layer connection 302 and a respective Through Array Via (TAV) element 305.

Each TAV element has a substantially cylindrical shape comprising an inner conductive plug surrounded by an outer insulating material.

It is possible to observe that the main extension of the cylindrical TAV elements 305 is substantially parallel to the z-direction, so that each TAV element 305 crosses at least one step of the staircase 300 through respective through hole(s) in the step(s), wherein the holes crossed by a TAV element 305 are substantially aligned over the z-direction and wherein the crossed steps are electrically insulated from the TAV elements 305 by means of the insulating layer of the TAV elements 305.

TAV elements 305 are coupled at one end portion to a respective common output terminal of the driver transistors 400 and 402 (not shown in FIG. 8) placed under the staircase area 306 of the memory device 100 wherein a word line driver 500 is realized; TAV elements 305 are coupled at another end portion to a respective conductive plug 304 by means of a respective metal layer connection 302.

The two driver transistors 400, 402 for driving a word line 205 at a given level 230 may be realized in the staircase area 306, as here below disclosed. The staircase area is adjacent to (e.g., neighbouring or proximate to but not overlapping) the active area, the active area comprising active cells.

Each TAV element 305 comprises an inner conductive plug 308 surrounded by an outer insulating material. Such a structure may extend through the word line material at each level 230, being electrically isolated therefrom.

The TAV elements 305 may be formed after the formation of the staircase 300. The conductive plugs 304 may be formed after formation of the staircase 300. The metal layer connections 302 (or jumpers) may be formed after formation of the TAV elements 305 and the conductive plugs 304.

The spatial disposition of TAV elements, metal layer connections and conductive plugs may vary from the disposition depicted in FIG. 8.

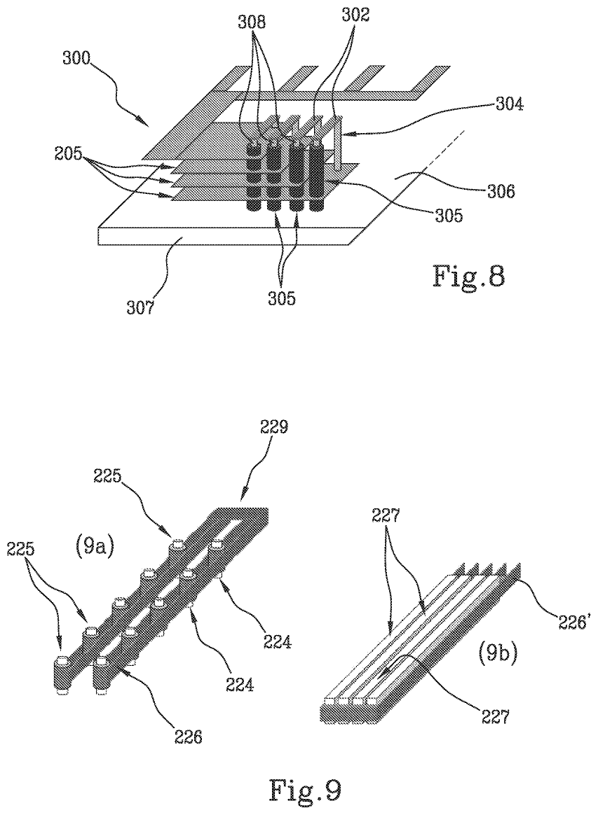

FIG. 9 shows two examples of Thin Film Transistors (TFT) arrangements that supports TFT-based word line decoding.

FIG. 9a depicts a plurality of TFT transistors 225 in the standard array configuration, e.g. in the same configuration as (or a configuration similar to) the configuration of TFT transistors 225 in the active area under the array of memory cells. As described above with reference to FIGS. 2 and 3A-3B, for example, in this active area each TFT transistor 225 is arranged to be placed under a respective pillar 220 and gate terminals of TFT transistors 225 are driven by a shared gate line (e.g., gate lines 210-a-5 or 210-a-3 in x-direction in FIGS. 3A and 3B, respectively).

Word line driving transistors 225 positioned in the staircase area 306 may use the same array configuration as above indicated for the TFT transistors 225 in the active area; the periodicity of the word line driving transistors 225 (e.g., relative distance, spacing and dimension) may be maintained in the staircase area 306, despite pillars 220 are absent in the staircase area 306 to form the steps 300a, 300b, 300c, 300d.

FIG. 9a shows a possible arrangement of a word line driving transistor, such as transistors 400 and/or 402 of FIG. 5.

The word line driving transistor comprises a plurality of TFT transistors 225 in parallel connection, each TFT transistor having a respective cylindrical portion 224 and a gate electrode 226, wherein each cylindrical portion 224 represents an active region (e.g., the channel, where it overlaps with the gate electrode 226, or the source and drain portions extending below or above the channel region).

TFT transistors 225 are placed between source and drain plates that are not shown in FIG. 9.

A gate connection 229 electrically shunts a plurality of gate lines 226 to increase the number of transistors in parallel connection and thus the driving capability.

As above explained, in the staircase area 306 it is possible to depart from the periodic arrangement of the TFT transistors of the active area of the array of memory cells. For example, in the staircase area 306 the gate line 226 may be differently patterned and/or multiple gate lines 226 may be electrically connected.

For example, in one embodiment (FIG. 9a) in the staircase area 306 it is possible to increase the driving capability by exploiting a parallel connection of a plurality of word line driving transistors 225 (e.g., 2×5 in the depicted example) by properly coupling respective drain nodes, source nodes (not shown) and gate nodes (e.g., via the gate connection 229 that electrically shunts a plurality of gate lines 226), therefore effectively forming a single word line driving TFT transistor 225. With this approach, the patterning of the word line driving TFT transistor 225 in the staircase area 306 may be the same as in the active area of the array of memory cells and only gate shunting or biasing need to be modified.

FIG. 9b shows another possible arrangement of a word line driving transistor, such as transistors 400 and/or 402 of FIG. 5.

The word line driving TFT transistors 227 in the staircase area 306 shares a common gate electrode 226′, wherein the active regions of the word line driving transistors 227 may be patterned differently from the ones realized in the active area of the array of memory cells. For example, the physical channel may be patterned in stripes (rather than in pillars, as in the active area of the array of memory cells) so that current may flow through a wider channel from/to drain to/from source terminals. In other words, just by modifying the TFT patterning, the TFT transistor channel width may be increased by eliminating the separation between otherwise adjacent TFTs (e.g., one TFT under each pillar 220), at least in one direction. FIG. 9b depicts a layout with four active stripes, each completely surrounded by a physically common gate electrode 226′. A gate connection 229′ may be provided to electrically shunt a plurality of gate lines 226′. Other active regions and gate line configurations are possible.

FIG. 10 shows a first example of a memory device 100′ that supports TFT-based word line decoding.

The memory device 100′ comprises a plurality of pairs of word line driving transistors 225 (in particular, Thin Film Transistors) arranged to be placed under the staircase 300 in the staircase area 306, wherein only four steps 300a, 300b, 300c and 300d of the staircase 300 are shown in FIG. 10; therefore only four pairs of word line driving transistors 225 are shown, each pair forming a word line driver 500.

Each step 300a, 300b, 300c, 300d is coupled to a respective word line 205 belonging to a corresponding level 230, as above discussed.

As it will be discussed in more detail below, each word line driving transistor 225 may comprise a plurality of transistors in parallel connection, in order to provide a higher driving capability with respect to a single transistor.

In the example depicted in FIG. 10, each pair of word line driving transistors 225 comprises one transistor comprising 30 transistors (arranged in a 6×5 array configuration) and comprises another transistor comprising 10 transistors (arranged in a 2×5 array configuration).

Other embodiments comprise a different number of word line levels (and corresponding number of steps in the word line staircase) and a different number of word line drivers (e.g., transistor pairs). Additionally, or alternatively, a different arrangement and/or number of parallel connected transistors in each driver transistor is also possible.

Word line driving transistors 225 placed in a central area are divided into internal blocks 500a, 500b, 500c, 500d.

As discussed below, each internal block 500a, 500b, 500c, 500d forms one driver transistor 400 configured to be connected to the second bias voltage V2 equal to an access voltage or to an inhibit voltage (for example, a ground reference voltage) as discussed above, and each internal block 500a, 500b, 500c, 500d selectively transfers such values to the corresponding word line.

Each driver transistor 400 comprises a drain terminal coupled to the second bias voltage V2, a gate terminal to activate or deactivate the driver transistor 400 and a source terminal coupled to the common node of the word line driver, e.g., finally connected to the word line.

The source terminal of each driver transistor 400 is connected, through a respective main TAV element 305a, . . . , 305d, to a respective upper metal layer connection (e.g. a metal line) 302a, . . . , 302d.

Each upper metal layer connection 302a, 302b, 302c, 302d is connected to a word line through a respective conductive plug 304a, 304b, 304c, 304d (that may correspond to the conductive plug 304 in FIG. 8) landing on a respective word line step 300a, . . . , 300d in the staircase area 306.

In other words, the second bias voltage V2 may be transferred to the desired word line via a driver transistor (formed by a parallel connection of transistors driven by a common gate terminal), a Through Array Via element, a metal layer connection and a conductive plug in between the metal layer connection and the word line step.

It is possible to observe in FIG. 10 the following:

TAV element 305a crosses one step 300a of the staircase 300, wherein the TAV element 305a is electrically insulated from the step 300a by means of the insulating layer on the TAV element 305a;

TAV element 305b crosses two steps 300a, 300b of the staircase 300, wherein the TAV element 305b is electrically insulated from the steps 300a, 300b by means of the insulating layer on the TAV element 305b;

TAV element 305c crosses three steps 300a, 300b, 300c of the staircase 300, wherein the TAV element 305c is electrically insulated from the steps 300a, 300b, 300c by means of the insulating layer on the TAV element 305c;

TAV element 305d crosses four steps 300a, 300b, 300c, 300d of the staircase 300, wherein the TAV element 305d is electrically insulated from the steps 300a, 300b, 300c, 300d by means of the insulating layer on the TAV element 305d.

More in particular, TAV element 305a extends over the z-direction and it has one bottom end portion electrically connected to word line driving Thin Film transistors 225 in block 500a and it has another top end portion electrically connected to a first portion the metal layer connection 302a, the metal layer connection 302a having a second portion connected to a first end portion of the conductive plug 304a, the conductive plug 304a having a second end portion connected to step 300a, which is connected to a first word line 205 at the lowest level, so that the first word line 205 may be selectively connected to the second bias voltage V2.

TAV element 305b extends over the z-direction and it has one bottom end portion electrically connected to word line driving Thin Film transistors 225 in block 502b and it has another top end portion electrically connected to a first portion of the metal layer connection 302b, the metal layer connection 302b having a second portion connected to a first end portion of the conductive plug 304b, the conductive plug 304b having a second end portion connected to step 300b, which is connected to a second word line 205 at an intermediate level, so that the second word line 205 may be selectively connected to the second bias voltage V2; moreover, a first TAV element 305bb has a bottom end portion electrically connected to word line driving Thin Film transistors 225 in block 502b and it has another top end portion electrically connected to a third portion of the metal layer connection 302b, so that the second word line 205 may also be selectively connected to the ground reference voltage.

TAV element 305c extends over the z-direction and it has one bottom end portion electrically connected to word line driving Thin Film transistors 225 in block 500c and it has another top end portion electrically connected to a first portion of the metal layer connection 302c, the metal layer connection 302c having a second portion connected to a first end portion of the conductive plug 304c, the conductive plug 304c having a second end portion connected to step 300c, which is connected to a third word line 205 at another higher intermediate level, so that the third word line 205 may be selectively connected to the second bias voltage V2; moreover, a second TAV element 305cc has a bottom end portion electrically connected to word line driving Thin Film transistors 225 in block 504b and it has another top end portion electrically connected to a third portion of the metal layer connection 302c, so that the third word line 205 may also be selectively connected to the ground reference voltage.

Finally, TAV element 305d extends over the z-direction and it has one bottom end portion electrically connected to word line driving Thin Film transistors 225 in block 500d and it has another top end portion electrically connected to a first portion of the metal layer connection 302d, the metal layer connection 302d having a second portion connected to a first end portion of the conductive plug 304d, the conductive plug 304d having a second end portion connected to step 300d, which is connected to a third word line 205 at the highest intermediate level, so that the fourth word line 205 may be selectively connected to the second bias voltage V2.

A first external block of transistors 502 and a second external block of transistors 504 are coupled to a ground reference voltage GND.

In particular, each external block of transistors 502, 504 comprises respectively an internal sub-block 502a, 504a and an external sub-block 502b, 504b. The two internal 502a, 504a and external 502b, 504b sub-blocks in each external block of transistors 502, 504 share a common terminal (e.g., to be coupled to the ground reference voltage GND), while the two internal 502a, 504a and external 502b, 504b sub-blocks have independent gate terminals 226a, 226b, 226c, 226d and independent drain terminals. In other words, in each external block of transistors 502, 504, the gate terminal of the internal sub-block is decoupled from the gate terminal of the external sub-block and drain terminal of the internal sub-block is decoupled from drain terminal of external sub-block.

The word lines (only the steps of which being shown in FIG. 10, positioned in the staircase area 306) connected to the respective upper metal layer connection 302a, . . . , 302d are selectively coupled to either the deselection reference voltage (for example, the ground reference voltage GND) or to the second bias voltage V2 (for example equal to +3.5 Volt or −3.5 Volt or 0 Volt) or are floating, the second bias voltage V2 being a read voltage or a write voltage and corresponding to the second bias voltage V2 of FIG. 5. In some configurations, the word line may be left floating.

With respect to the connection to the second bias voltage V2, the upper metal layer connections 302a, . . . , 302d may be connected through the respective main TAV elements 305a, . . . , 305d and respective driver transistor in blocks 500a, . . . , 500d to said second bias voltage V2.

With respect to the connection to the ground reference voltage GND, a first upper metal layer connection 302a and a fourth upper metal layer connection 302d (i.e., the ones connected to the most external TAV elements 305a, 305d, respectively) may be connected to the ground reference voltage GND through the respective TAV elements 305a, 305d. Connecting plate 506a is a common node comprising an upper terminal of transistor 225 in block 500a and an upper terminal of transistor 225 in sub-block 502a; the common node can be grounded by transistors 225 in sub-block 502a. Connecting plate 506b is a common node comprising an upper terminal of transistor 225 in block 500d and an upper terminal of transistor 225 in sub-block 504a; the common node can be grounded by transistors 225 in sub-block 504a.

By activating transistors in blocks 502a, 504a through the appropriate gate biasing of the respective gate terminals 226b, 226c, the plates 506a, 506b may be selectively biased to the ground reference voltage, and so the word lines coupled thereto via TAV elements 305a, 305d, upper metal layer connections 302a, 302d, conductive plugs 304a, 304d and steps 300a, 300d).

A second upper metal layer connection 302b and a third upper metal layer connection 302c (i.e., the ones connected to the most internal TAV elements 305b, 305c, respectively) are coupled to the upper terminals of the word line driving transistors 225 of the external sub block 502b, 504b of the first external block of transistors and of the second external block of transistors, respectively, through respective external TAV elements 305bb and 305cc. By activating transistors 502b, 504b through the appropriate biasing of the respective gate terminals 226a, 226d, plates 506c, 506d may be selectively biased to the ground reference voltage, and so the word lines coupled thereto via TAV elements 305bb and 305cc, upper metal layer connections 302b, 302c, conductive plugs 304b, 304c and steps 300b, 300c.

In the above-illustrated structure, for each word line connected to the upper metal layer connections 302a, . . . , 302d, the two word line driving transistors correspond to the n-MOS driver transistors 400, 402 of FIG. 5 in the following manner.

The plurality of word line driving transistors 225 of the first block 500a, second block 500b, third block 500c, fourth block 500d, respectively, each correspond to n-MOS driver transistor 400 of respective word line driver coupled to respective upper metal layer connections 302a, 302b, 302c, 302d, and they have one driving terminal (e.g., a drain terminal) biased to the second bias voltage V2, a respective gate terminal 226e1, 226e2, 226e3, 226e4 (corresponding to the first bias voltage V1 of FIG. 5) and the other terminal (e.g., a source terminal) coupled to the respective TAV elements 305a, 305b, 305c, 305d (corresponding to the output voltage V_{WL} of FIG. 5).

The plurality of word line driving transistors 225 of the internal sub block 502a of the first external block of transistors 502 correspond to a n-MOS driver transistor 402 of a word line driver 400 coupled to the first upper metal layer connection 302a, and it has a reference terminal (e.g., a source terminal) biased to the deselection reference voltage (for example, equal to the ground reference voltage GND), it has a gate terminal 226b (corresponding to the third bias voltage V3 of FIG. 5) and it has the other terminal (e.g., a drain terminal) coupled to the first TAV element 305a (corresponding to the output voltage V_{WL} of FIG. 5) for biasing a word line, e.g., word line connected to step 300a. The plurality of word line driving transistors 225 of the external sub block 502b of the first external block of transistors 502 correspond to another n-MOS driver transistor 402 coupled to metal layer connection 302b via TAV element 305bb for biasing a different word line, e.g., word line connected to step 300b.

Similarly, the plurality of the word line driving transistors 225 of the internal sub block 504a of the second external block of transistors 504 correspond to an n-MOS driver transistor 402 of a word line driver 400 coupled to fourth upper metal layer connection 302d, and it has a reference terminal (e.g., a source terminal) biased to the deselection reference voltage (for example, equal to the ground reference voltage GND), it has a gate terminal 226c (corresponding to the third bias voltage V3 of FIG. 5) and it has the other terminal (e.g., a drain terminal) coupled to the fourth TAV element 305d (corresponding to the output voltage V_{WL} of FIG. 5) for biasing a different word line, e.g., word line connected to step 300d. The plurality of the word line driving transistors 225 of the external sub block 504b of the second external block of transistors 504 correspond to another n-MOS driver transistor 402 coupled to metal layer connection 302c via TAV element 305cc for biasing a different word line, e.g., word line connected to step 300c.

The gate electrodes 226a, 226b, 226c, 226d, 226e1, 226e2, 226e3, 226e4 of each plurality of the word line driving transistors 225 may be contacted in a back area 600 where they extend towards a background of FIG. 10. Accordingly, each of the word line driving transistors in blocks 500a, 500b, 500c, 500d and in sub-blocks 502a, 502b, 504a, 504b may be selectively driven by a sole respective gate signal.

According to the example depicted in FIG. 10, a first pair of word line driver transistors 400, 402 comprises TFT transistors in blocks 500a and 502a. Blocks 500a and 502a may be associated to the word line connected to step 300a. According to the example depicted in FIG. 10, a second pair of word line driver transistors 400, 402 comprises TFT transistors in blocks 500b and 502b. Blocks 500b and 502b may be associated to the word line connected to step 300b. According to the example depicted in FIG. 10, a third pair of word line driver transistors 400, 402 comprises TFT transistors 500c and 504b. Blocks 500c and 504b may be associated to the word line connected to step 300c. According to the example depicted in FIG. 10, a fourth pair of word line driver transistors 400, 402 comprises TFT transistors in blocks 500d and 504a. Blocks 500d and 504a may be associated to the word line connected to step 300d.

It should be understood that FIG. 10 depicts one specific embodiment, while other implementations are possible. For example, any or all of transistors in blocks 500a, 500b, 500c and 500d (corresponding to word line driver transistor 400 in FIG. 5) and transistors 502a, 502b, 504b and 504a (corresponding to driver transistors 402 in FIG. 5) may be different than depicted in FIG. 10 in shape, dimension, etc. For example, a higher or a lower number of word line driving transistors 225 in parallel connection may be used (with respect to the 6×5 and 2×5 pluralities shown for driver transistors 400 and 402, respectively). The pitch, e.g., dimension of and/or spacing between adjacent individual active elements forming driver transistors 400 and/or 402 in the staircase area may be different than a pitch, e.g., dimension and/or spacing, of transistors 225 coupled to the memory cells 205 through pillars 220 in the active area of the memory array.

Additionally, or alternatively, any or all of driver transistors 400 and 402 may be formed differently than depicted in FIG. 10 (where each transistor substantially corresponds to the TFT transistor arrangement depicted in FIG. 9a). For example, driver transistors 400 and/or 402 may be formed with a TFT transistor arrangement that is the same as, or similar to, the one depicted in FIG. 9b (e.g., with active area and gate electrode patterned differently than in the configuration of individual transistors 225 coupled to the memory cells 205 through pillars 220 in the active area of the memory array).

The connection to the terminals of any or all of driver transistors 400 and 402 may be different than those depicted in FIG. 10; for example, in another embodiment (not shown in the drawings) electrically independent drain terminals may be provided to each of the transistors 400 for biasing each of them at a respective V2 voltage and/or one or more common gate terminals of driver transistors 400 and 402 may be provided to drive the first bias voltage V1 and the third bias voltage V3.

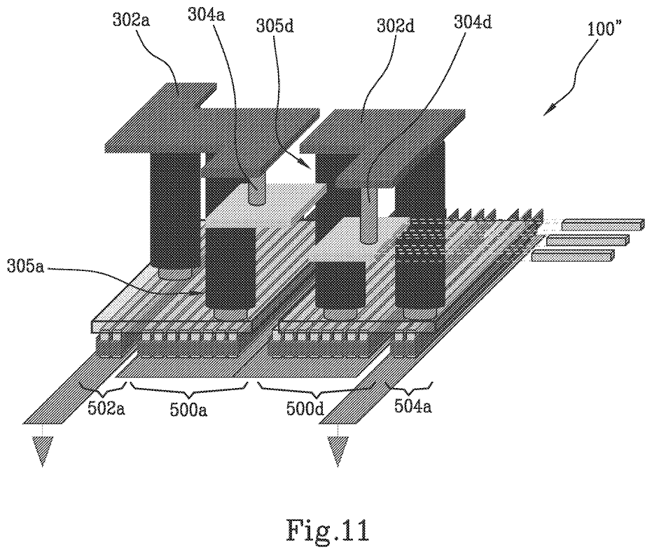

FIG. 11 shows a second example of a memory device 100″ that supports TFT-based word line which is similar to the one above disclosed with reference to FIG. 10.

Memory device 100″ comprises TFT word line drivers, only two of which are depicted in FIG. 11 for clarity.

In particular, FIG. 11 shows word line driving TFT transistors of the first and fourth internal block 500a, 500d as depicted in FIG. 10 (corresponding to driver transistor 400 of word line driver 500 in FIG. 5) and word line driving TFT transistors of the internal sub-blocks 502a, 504a as depicted in FIG. 10 (corresponding to driver transistors 402 of word line driver 500 in FIG. 5).

Memory device 100″ further comprises source/drain electrodes of respective transistors, configured to be coupled to the second bias voltage V2 and to the ground reference voltage, respectively.

Memory device 100″ also comprises through array via elements 305a, 305d coupled between drain/source electrodes of respective TFT transistors and upper metal layer connections 302a, 302d. Each upper metal layer connection 302a, 302d is coupled to a respective word line through a respective conductive plug 304a, 304d landing on the corresponding tread of the step 300a, 300d in the staircase 300.

Each transistor in blocks 500a, 500d, 502a, 504a comprises a plurality of TFT transistors in parallel connection. In the example depicted in FIG. 11, the word line driving TFT transistors comprise a plurality of elongated active areas completely surrounded by a common gate electrode. In the depicted example, each of TFT transistors 502a and 504a comprises two active area stripes, while each of TFT transistors in blocks 500a and 500d comprises eight active area stripes. It is understood that the depicted example is not limiting and that any number of stripes may be used for any of the transistors. In some embodiments, the number of active area stripes, e.g., the overall channel width, of the TFT transistors in blocks 500a, 500d coupled between the second bias voltage V2 and the output node of the word line driver is higher than a number of stripes (two active area stripes each in the example depicted in FIG. 11), e.g., a respective channel width, of the TFT transistors in blocks 502a, 504a coupled between the deselection reference voltage (for example equal to the ground reference voltage GND) and the common node of the word line driver. In other embodiments, the TFT transistors may have an equal number of active area stripes, that is an equal channel width.

The TFT transistors in the example of FIG. 11 may be examples of word line driving TFT transistors described with reference to FIG. 9b. However, different types of TFT transistors may be used; for example, TFT transistors as or similar to the transistors discussed above with reference to FIG. 9a may also be used.

In other words, some embodiments may comprise a plurality of transistors in parallel connection to form the word line driving transistors, wherein each driving transistor of the plurality may have a pillar-like channel as transistors 225 present in the active area of the memory array.

In a similar fashion as described with reference to FIG. 10, one word line TFT driver may comprise transistor in block 500a (corresponding to driver transistor 400) configured to have a drain node biased to the second bias voltage V2 equal to an access voltage or to an inhibit voltage (for example, a ground reference voltage) and transistor 502a (corresponding to driver transistor 402) configured to have a source node biased to a deselection reference voltage (for example, a ground reference voltage GND). The second bias voltage V2 equal to the access voltage or inhibit voltage (or the ground reference voltage GND) may be transferred to the common node of the word line driver based on the value of the first bias voltage V1 applied to the gate terminal of transistor in block 500a (or based on the value of the third bias voltage V3 applied to the gate terminal of transistor 502a, respectively). The voltage of the common node is transferred by TAV element 305a to the metal layer connection 302a and through conductive plug 304a to the corresponding word line step (the word line connected to this step is not shown in FIG. 11).

Similarly, another word line TFT driver may comprise transistor in block 500d (corresponding to driver transistor 400) configured to have a drain node biased to the second bias voltage V2 equal to the access voltage or to an inhibit voltage (for example, a ground reference voltage) and transistor 504a (corresponding to driver transistor 402) configured to have a source node biased to a deselection reference voltage (for example, a ground reference voltage GND). The second bias voltage V2 equal to the access voltage or inhibit voltage (or the ground reference voltage GND) may be transferred to the common node of the word line driver based on the value of the first bias voltage V1 applied to the gate terminal of transistor 500d (or based on the value of the third bias voltage V3 applied to the gate terminal of transistor 504a, respectively). The voltage of the common node is transferred by TAV element 305d to the metal layer connection 302d and through the conductive plug 304d to the corresponding word line step (on the right side of FIG. 11 portions of the word line connected to this step are also shown).

In the memory device 100″, the common node of each of word line drivers is coupled to the corresponding metal layer connection with two TAV elements and the metal layer connection is coupled to the word line step with one conductive plug. It is understood than any number of TAV elements and/or of conductive plugs may be used; generally speaking, a higher the number of TAV elements and/or conductive plugs corresponds to a smaller resistance (e.g., a better coupling). For example, as far as functionality is concerned, a single TAV element and a single plug are sufficient for each of TFT word line driver.

The connection to the terminals of any or all of driver transistors 400 and 402 may be different than those depicted in FIG. 11; for example, in another embodiment (not shown in the drawings) electrically independent drain terminals may be provided to each of the transistors 400 for biasing each of them at a respective V2 voltage and/or one or more common gate terminals of driver transistors 400 and 402 may be provided to drive the first bias voltage V1 and the third bias voltage V3.

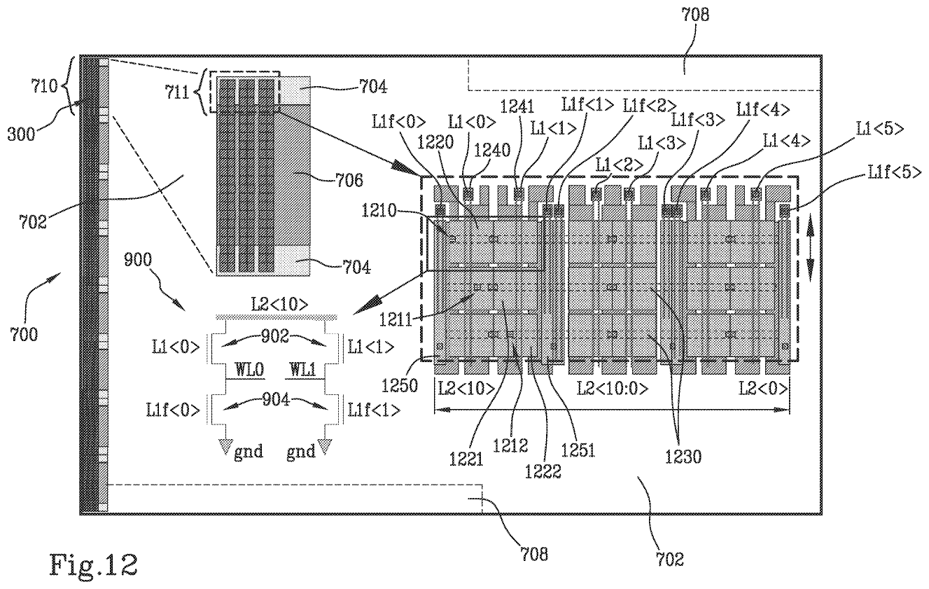

FIG. 12 shows a top view of a tile 700 in an array of a memory device 100′ or 100″ that supports TFT-based word line decoding with an enlarged view of the staircase area 306. In particular, a staircase area 710 (which includes the staircase area 306 as described above) is depicted with an enlarged scale and another area 711 (which is a portion of the staircase area 710) is depicted with a further enlarged scale.

Finally, a schematic diagram 900 is also represented.

The embodiment depicted in FIG. 12 may correspond to the embodiment depicted in FIG. 10 or 11, for example.

A staircase 300 is present at a border of the array tile 700, e.g., the staircase area is adjacent to (e.g., neighbouring or proximate to but not overlapping) the active area, the active area comprising active cells. In staircase area 710, steps 300a, 300b, 300c, 300d may be provided for contacting word lines 205 at respective levels, as depicted for example in FIGS. 4 and 10-11.

A central active area 702 of the array tile 700 may accommodate the active area of the array of memory cells, such as described above with reference to FIGS. 2 and 3.

A portion 708 of the active area 702 may accommodate the gate line drivers for driving the gate lines connected to the gate terminals of the transistors of memory cells in the active area 702 of the array tile.

In the staircase area 710, e.g. under the staircase 300 and possibly extending into the active area 702 of the memory array (see the first inset depicting an enlarged view of the staircase area 710), a first area 704 may accommodate circuitry to selectively generate the values of the first bias voltage V1 and third bias voltage V3 for word line driving transistors (e.g. driver transistors 400 and 402 in FIG. 5 and/or transistors in blocks 500a and 502a in FIGS. 10 and 11).

The circuitry in the first area 704, commonly referred to as gate drivers, is sometimes referred to as L1 drivers (to generate the first bias voltage V1) and L1f drivers (to generate the third bias voltage V3).

A second area 706 may include a voltage supply generator to selectively generate the second bias voltage V2 for word line driving transistors (e.g. driver transistors 400 and 402 in FIG. 5 and/or transistors in blocks 500a and 502a in FIGS. 10 and 11).

The voltage supply generator in the second area 706 is sometimes referred to as L2 drivers (to generate the second bias voltage V2).

In some embodiments, an additional area (not shown, possibly adjacent to areas 704 and 706) may accommodate a voltage supply generator to selectively generate voltages for driving bit lines of the memory array, such digit line or bit line access voltages.

A second inset of FIG. 12 shows a further enlarged top view of the area 711 inside the staircase area 710. In the second inset, a possible arrangement of word line drivers is represented. The depicted layout comprises word line drivers organized in rows (only the top three rows are represented) and columns (six columns-note that due to layout optimization by specular placement of elements, three main columns appear more evident in the second inset).

It is understood that the number of rows and columns may be different than as displayed in FIG. 12. The number of word line drivers in each row and the number of rows may be based on a total number of word line layers to be addressed.

In the second inset, a bus of lines L2<10: 0> runs vertically; each line of the bus carries a signal corresponding to the second bias voltage V2. The second bias voltage V2 voltage for each line L2 may be selectively generated and/or provided by circuits in the second area 706.

A contact 1210, 1211, 1212 couples each L2 signal line to a corresponding bottom electrode of a driving TFT transistor in one row. For example, line L2<10> is only coupled to electrode 1220 via contact 1210. Similarly, line L2<09> is only coupled to electrode 1221 in the second row via contact 1211, line L2<08> is only coupled to electrode 1222 in the third row via contact 1212, and so on.

In the described embodiment, all bottom electrodes of driving transistors 400 in the same row are biased to the same value of the second bias voltage V2; in the depicted example this may be achieved either because the bottom electrode is shared (e.g., as depicted in FIG. 11 and here also represented for adjacent electrodes) or via a shunt connection 1230 at a different metal level. With the approach described above, it is possible to avoid L2 bus duplication and improve area occupancy with respect to line resistivity.

Signals L1, carrying gate selection of the first bias voltage V1 for TFT word line drivers, may be generated and/or provided by circuits in area 704 and are provided through corresponding lines. For example, signals L1<0> and L1<1> are generated by gate drivers and signals L1<0> is provided through line 1240 and signal L1<1> is provided through line 1241 and bias respective gate lines, e.g., gate line of transistor 400 in block 500a and of transistor 400 in block 500d, respectively (see FIG. 11).

As illustrated in FIG. 12, the value of the first bias voltage V1 of gate lines is shared among all transistors 400 in the same column that, however, will have selectively different (e.g., by row) values of the second bias voltage V2, based on whether the corresponding word lines are selected or unselected.

A deselection reference voltage (for example, the ground reference voltage) may be applied to bottom electrodes 1250, 1251 of transistors 402 in blocks 502a, 504a.

The gate electrodes of transistors 402 in blocks 502a and 504a may be selectively driven to the third bias voltage V3 by L1f<0> and L1f<1> signals, respectively. L1f signals and/or third bias voltages V3 may be generated and/or provided by circuits (e.g., gate drivers) in the area 704.

As illustrated in FIG. 12, signal lines Lf are also shared among the transistors in the same column that, however, will have selectively different values (e.g., by row) of the second bias voltage V2, based on whether the corresponding word lines are selected or unselected.

For improved clarity, the second inset does not show the active region of TFT transistors nor the top electrode.

The TFT active regions overlap respective bottom electrode portions, while the top electrodes, that may also be the TFT word line output node, are shared between the transistor coupled to ground reference voltage and the transistor coupled to the second bias voltage V2, as depicted in FIG. 11.

TAV elements, the metal layer connections and the plugs for connection of top electrodes to word line step (not shown, either) are also provided.

Circuit 900 represents the pair of TFT word line drivers that share a common bottom electrode biased at the second bias voltage V2 (for example carried by signal line L2<10>). In each branch from the second bias voltage V2 to the deselection reference voltage (for example, the ground reference voltage GND), a pull-up transistor 902 (corresponding to the driver transistor 400 in FIG. 4, or transistor in blocks 500a, 500d in FIG. 11) and a pull-down transistor 904 (corresponding to the driver transistor 402, or transistor in blocks 502a, 504a) are present.

Pull-up transistors 902 may be selectively driven at the first bias voltage V1 provided by respective signal line L1<0> (for transistor in block 500a) and L1<1> (for transistor in block 500d), for example.

Pull-down transistors 904 may be selectively driven at the third bias voltage V3 provided by respective signal line L1f<0> (for transistor 502a) and L1f<1> (for transistor in block 504a), for example.

Therefore, either the second bias voltage V2 voltage on the bottom electrode or the ground reference voltage GND are transferred to the shared top electrode, e.g. to the TFT word line driver output WL0, WL1 for biasing the associated word line through the corresponding TAV element, metal layer conduction, plug and word line step of the staircase.

Similar signal and voltage distribution layouts may be developed based on the above description modifying, for example and among others, the number of rows and columns and, accordingly, the number of L2 bus lines, the locations of contacts between L2 lines and bottom electrodes, the shunting of bottom electrodes, the number and location of L1 and L1f lines.

FIG. 13 shows a flowchart illustrating a method 800 for driving word lines in a memory device in accordance with examples as disclosed herein, wherein a plurality of memory cells are arranged in a three-dimensional array comprising a plurality of levels above a substrate, the memory device comprising a plurality of conductive word lines extending over a respective level and coupled to said plurality of memory cells, each word line being connected to a respective step of a staircase positioned in a staircase area (306, 710).

The steps of the driving method 800 may be implemented by means of a memory device 100′, 100″ as described herein.

In some examples, a memory device 100′, 100″ may execute a set of instructions to control the functional elements of the device to perform the described functions. Additionally, or alternatively, the memory device 100′, 100″ may perform aspects of the described functions using special-purpose hardware.

The driving method 800 includes the step 801 of selectively enabling: a first TFT 400 of a word line driver, the first TFT positioned in the staircase area and coupled between to word line, by means of a Through Array Via-TAV-element, to selectively bias the word line to a bias voltage (for example, the second bias voltage V2) applied to a driving terminal of the word line driver, the bias voltage being equal to an access voltage or an inhibit voltage; or a second TFT 402 of said word line driver, the second TFT positioned in the staircase area and coupled to said word line through a common node of the first thin film transistors 400 and the second thin film transistors 402, to selectively bias the word line to a deselection reference voltage (for example, a ground reference voltage) applied to a reference terminal of the second TFT.

In one embodiment, the driving method 800 includes biasing a word line to the access voltage V2 (for example V2=+3.5 Volt) by means of biasing the driving terminal of the first TFT to the access voltage V2 greater than a ground reference voltage (i.e. 0 Volt), biasing a gate terminal of the first TFT to an activation voltage V1 greater than the access voltage (for example, V1=+5 Volt), biasing the reference terminal of the second TFT to the ground reference voltage, and biasing a gate terminal of the second TFT to a deactivation voltage V3 smaller than the ground reference voltage (for example, V3=−3.5 Volt).

In one embodiment, the driving method 800 includes biasing the word line to the ground reference voltage (i.e. 0 Volt) by means of biasing the driving terminal of the first TFT to the access voltage V2 greater than the ground reference voltage (for example V2=+3.5 Volt), biasing a gate terminal of the first TFT to a deactivation voltage V1 smaller than the ground reference voltage (for example, V1=−3.5 Volt), biasing the reference terminal of the second TFT to the ground reference voltage, and biasing a gate terminal of the second TFT to an activation voltage V3 greater than the ground reference voltage (for example, V3=+2 Volt).

In one embodiment, the driving method 800 includes biasing the word line to a ground reference voltage (i.e. 0 Volt) by means of biasing the driving terminal of the first TFT to the ground reference voltage, biasing a gate terminal of the first TFT to an activation voltage V1 greater than the ground reference voltage (for example, V1=+5 Volt), biasing the reference terminal of the second TFT to the ground reference voltage, and biasing a gate terminal of the second TFT to a deactivation voltage (V3) smaller than the ground reference voltage (for example, V3=−3.5 Volt).

In one embodiment, the driving method includes biasing the word line to a ground reference voltage by means of biasing the driving terminal of the first TFT to the ground reference voltage, biasing a gate terminal of the first TFT to a deactivation voltage (V1) smaller than the ground reference voltage (for example, V1=−3.5 Volt), biasing the reference terminal of the second TFT to the ground reference voltage, and biasing a gate terminal of the second TFT to an activation voltage V3 greater than the ground reference voltage (for example, V3=+2 Volt).

In one embodiment, the driving method 800 includes biasing a word line to the access voltage V2 (for example V2=−3.5 Volt) by means of biasing the driving terminal of the first TFT to the access voltage V2 smaller than a ground reference voltage (i.e. 0 Volt), biasing a gate terminal of the first TFT to an activation voltage equal to the ground reference voltage, biasing the reference terminal of the second TFT to the ground reference voltage, and biasing a gate terminal of the second TFT to a deactivation voltage V3 smaller than the ground reference voltage (for example, V3=−3.5 Volt).

In one embodiment, the driving method 800 includes biasing the word line to a ground reference voltage (i.e. 0 Volt) by means of biasing the driving terminal of the first TFT to the access voltage V2 smaller than the ground reference voltage (for example V2=−3.5 Volt), biasing a gate terminal of the first TFT to a deactivation voltage V1 smaller than the ground reference voltage (for example, V1=−3.5 Volt), biasing the reference terminal of the second TFT to the ground reference voltage, and biasing a gate terminal of the second TFT to an activation voltage V3 greater than the ground reference voltage (for example, V3=+2 Volt).

In one embodiment, the driving method 800 includes driving the word line to floating by means of biasing the driving terminal of the first TFT to the ground reference voltage, biasing a gate terminal of the first TFT to an activation voltage equal to the ground reference voltage, biasing the reference terminal of the second TFT to the ground reference voltage, and biasing a gate terminal of the second TFT to a deactivation voltage (V3) smaller than the ground reference voltage (for example, V3=−3.5 Volt).

In one embodiment, the driving method includes biasing the word line to a ground reference voltage by means of biasing the driving terminal of the first TFT to the ground reference voltage, biasing a gate terminal of the first TFT to a deactivation voltage (V1) smaller than the ground reference voltage (for example, V1=−3.5 Volt), biasing the reference terminal of the second TFT to the ground reference voltage, and biasing a gate terminal of the second TFT to an activation voltage V3 greater than the ground reference voltage (for example, V3=+2 Volt).

Information and signals described herein may be represented using any of a variety of different technologies and techniques. For example, signals that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. A memory device comprising:
a plurality of memory cells arranged in a three-dimensional array comprising a plurality of levels above a substrate;
a plurality of conductive word lines extending over a respective level and coupled to said plurality of memory cells, each word line being connected to a respective step of a staircase positioned in a staircase area outside an active area of the array of the plurality of memory cells;
a plurality of word line drivers for the corresponding plurality of word lines, each word line driver comprising at least one first thin film transistor and at least one second thin film transistor;
a plurality of Through Array Via (TAV) elements for the corresponding plurality of word lines, each TAV element being coupled at a first end portion to a respective word line through a respective step of the staircase and being coupled at a second end portion to a common node of the respective at least one first and at least one second thin film transistors;
wherein the plurality of word line drivers and the plurality of TAV elements are positioned in the staircase area.

2. The memory device of claim 1, wherein each of the plurality of TAV elements includes a respective conductive plug surrounded by an external insulating layer,
each TAV element having a main extension extending across the plurality of levels of the array,
each TAV element crossing at least one step of the staircase through respective through hole(s) in the step(s).

3. The memory device of claim 1, further comprising a plurality of plugs for the corresponding plurality of word lines and a plurality of metal layers connections, each plug being coupled at a first end portion to a respective step of the staircase and being coupled at a second end portion to the first end portion of a respective TAV element through a respective metal layer connection,
wherein the plurality of plugs and the plurality of metal layer connections are positioned in the staircase area.

4. The memory device of claim 1, wherein the at least one first thin film transistor of at least one word line driver comprises respective internal blocks of thin film transistors, each internal block being coupled, through a respective Through Array Via element and a corresponding metal layer connection, to a respective step of the staircase,
and wherein the at least one second thin film transistor of the at least one word line driver comprises respective first and second external blocks of thin film transistors, wherein the thin film transistors of the internal blocks are coupled to a bias voltage (V2),
and wherein the thin film transistors of the first and second external block are coupled to a ground reference voltage (GND).

5. The memory device of claim 4, wherein each external block of thin film transistors comprises a respective internal sub-block and a respective external sub-block, the internal and external sub-blocks sharing a common terminal (GND) and the internal and external sub-blocks having independent gate terminals and independent drain terminals.

6. The memory device of claim 4, wherein a first metal layer connection and a fourth metal layer connection are coupled to the ground reference voltage through the respective Through Array Via element and first and second connecting plates, respectively, so that by activating the thin film transistors of internal sub blocks through a gate biasing of respective gate terminals, the first and second connecting plates are selectively coupled to the ground reference voltage.

7. The memory device of claim 6, wherein a second metal layer connection and a third metal layer connection are coupled to upper terminals of thin film transistors of external sub blocks of the first external block of transistors and of the second external block of transistors, respectively, through respective external Through Array Via element, so that by activating the thin film transistors of the external sub blocks through a gate biasing of respective gate terminals, the plates are selectively coupled to the ground reference voltage.

8. The memory device of claim 1, further comprising a voltage supply generator for generating a second bias voltage (V2) for selectively biasing a driving terminal of each of the at least one first thin film transistor to an access voltage or inhibit voltage, wherein the voltage supply generator is positioned in a portion of the staircase area.

9. The memory device of claim 1, wherein at least one first thin film transistor (TFT) and at least one second TFT comprise respective gate terminals,
the memory device further comprising a plurality of gate lines coupled to respective gate terminals of the least one first and second TFT,
the memory device further comprising a gate driver for selectively driving the plurality of gate lines,
wherein the gate driver is positioned in another portion of the staircase area.

10. The memory device of claim 1, wherein the staircase area is adjacent to the active area, the active area comprising active cells.

11. A method for driving a word line in a memory device, wherein a plurality of memory cells are arranged in a three-dimensional array comprising a plurality of levels above a substrate, the memory device comprising a plurality of conductive word lines extending over a respective level and coupled to said plurality of memory cells, each word line being connected to a respective step of a staircase positioned in a staircase area, the method comprising selectively enabling:
a first Thin Film Transistor (TFT) of a word line driver, the first TFT positioned in the staircase area and coupled to a word line, by means of a through array via element, to selectively bias the word line to a bias voltage (V2) applied to a driving terminal of the word line driver, the bias voltage being equal to an access voltage or an inhibit voltage; or
a second TFT of said word line driver, the second TFT positioned in the staircase area and coupled to said word line through a common node of the first and the second thin film transistors, to selectively bias the word line to a reference voltage applied to a reference terminal of the word line driver.

12. The driving method of claim 11, including biasing the word line to the access voltage by means of:
biasing the driving terminal of the first TFT to the access voltage (V2) greater than a ground reference voltage;
biasing a gate terminal of the first TFT to an activation voltage (V1) greater than the access voltage;
biasing the reference terminal of the second TFT to the ground reference voltage; and
biasing a gate terminal of the second TFT to a deactivation voltage (V3) smaller than the ground reference voltage.

13. The driving method of claim 11, including biasing the word line to a ground reference voltage by means of:
biasing the driving terminal of the first TFT to the access voltage (V2) greater than the ground reference voltage;
biasing a gate terminal of the first TFT to a deactivation voltage (V1) smaller than the ground reference voltage;
biasing the reference terminal of the second TFT to the ground reference voltage; and
biasing a gate terminal of the second TFT to an activation voltage (V3) greater than the ground reference voltage.

14. The driving method of claim 11, including biasing the word line to ground reference voltage by means of:
biasing the driving terminal of the first TFT to the ground reference voltage;
biasing a gate terminal of the first TFT to an activation voltage (V1) greater than the ground reference voltage;
biasing the reference terminal of the second TFT to the ground reference voltage; and
biasing a gate terminal of the second TFT to a deactivation voltage (V3) smaller than the ground reference voltage.

15. The driving method of claim 11, including biasing the word line to ground reference voltage by means of:
biasing the driving terminal of the first TFT to the ground reference voltage;
biasing a gate terminal of the first TFT to a deactivation voltage (V1) smaller than the ground reference voltage;
biasing the reference terminal of the second TFT to the ground reference voltage;
biasing a gate terminal of the second TFT to an activation voltage (V3) greater than the ground reference voltage.

16. A word line decoder for a memory device comprising a plurality of memory cells arranged in a three-dimensional array comprising a plurality of levels above a substrate, the decoder comprising:
a plurality of word line drivers for a corresponding plurality of word lines extending over the corresponding plurality of levels, wherein each word line driver comprises:
at least one first thin film transistor and at least one second thin film transistor;
a respective at least one driving terminal of the first thin film transistor coupled to a bias voltage (V2) equal to an access voltage or an inhibit voltage, to selectively bias the respective word line to the bias voltage;
a respective at least one reference terminal of the second thin film transistor coupled to a reference voltage, to selectively bias the respective word line to the reference voltage;
a plurality of Through Array Via (TAV) elements for the corresponding plurality of word lines, each TAV element being coupled between a respective word line and a respective common node of the at least one first thin film transistor and the at least one second thin film transistor;
wherein the plurality of word line drivers and the plurality of TAV elements are positioned in a staircase area outside an active area of the array of the plurality of memory cells.

17. The word line decoder of claim 16, wherein each of the plurality of TAV elements includes a respective conductive plug surrounded by an external insulating layer,
each TAV element having a main extension extending across the plurality of levels of the array,
each TAV element crossing at least one step of the staircase through respective through hole(s) in the step(s).

18. The word line decoder of claim 16, further comprising a plurality of plugs for the corresponding plurality of word lines and a plurality of metal layers connections, each plug being coupled at a first end portion to a respective step of the staircase and being coupled at a second end portion to the first end portion of a respective TAV element through a respective metal layer connection,
wherein the plurality of plugs and the plurality of metal layer connections are positioned in the staircase area.

19. The word line decoder of claim 16, further comprising:
a voltage supply generator for generating the bias voltage (V2), wherein the voltage supply generator is positioned in a portion of the staircase area; and
a gate driver for selectively driving a plurality of gate lines, wherein the gate driver is positioned in another portion of the staircase area.

20. The word line decoder of claim 16 wherein the staircase area is adjacent to the active area, the active area comprising active cells.

21. The word line decoder of claim 16 wherein the word line drivers are organized in rows and columns, the word line decoder further comprising:
a bus of lines, each line of the bus configured to carry a signal corresponding to the second bias voltage (V2) to the respective at least one driving terminal of the first thin film transistor of the word line drivers in one row;
second lines configured to carry gate selection signals (V1) to the respective at least one control terminal of the first thin film transistor of the word line drivers in one column; and
third lines configured to carry gate selection signals (V3) to the respective at least one control terminal of the second thin film transistor of the word line drivers in one column.
